(19) United States
(12) Patent Application Publication
(10) Pub. No.: US 2025/0056764 A1
(43) Pub. Date: Feb. 13, 2025

(54) HEAT-CONDUCTING PLATE

(71) Applicant: 9351-0618 QUÉBEC INC., Sherbrooke (CA)

(72) Inventors: Mahmoodreza SALIM SHIRAZY, Boucherville (CA); Luc FRECHETTE, Sherbrooke (CA)

(21) Appl. No.: 18/720,323

(22) PCT Filed: Dec. 15, 2022
(86) PCT No.: PCT/CA2022/051825

§ 371 Date: Jun. 14, 2024

Related U.S. Application Data
(60) Provisional application No. 63/290,752, filed on Dec. 17, 2021.

(51) Int. Cl. H05K 7/20; B21D 53/04

(52) U.S. Cl. CPC H05K 7/20336; B21D 53/04; H05K 7/20936

(57) ABSTRACT

A heat-conducting plate that includes a vapour chamber is manufactured by disposing a vapor core and a wicking layer inside a cavity defined between spaced-apart walls of a casing, injecting a working fluid inside the cavity, and applying a vacuum to the cavity. After the applying of the vacuum to the cavity, the peripheries of the spaced-apart walls are cold welding to one another to seal the working fluid and the vapor core and the wicking layer in the cavity.

### CROSS-REFERENCE TO RELATED APPLICATIONS

This application claims priority on U.S. patent application No. 63/290,752 filed Dec. 17, 2021, the entire contents of which are incorporated herein by reference.

### TECHNICAL FIELD

This disclosure generally relates to heat transfer devices and, more particularly, to the heat pipes operable to transfer heat between two components.

### BACKGROUND

Electric vehicles and other types of electric equipment may be powered by one or more electric batteries. Each battery typically includes a plurality of cells that are operatively connected to one another. Such batteries generate heat when power is drawn from them. In some cases, operating batteries when temperatures of the batteries exceeds a maximum temperature threshold, which may be caused by hot ambient temperatures, may impede their performance and, in some cases, may damage the batteries. Additionally, performance of the batteries may decrease when they are operated at a temperate below a minimum temperature threshold. While attempts to better regulate the temperature of batteries have been made, improvements are nonetheless sought.

### SUMMARY

In one aspect, there is provided a method of manufacturing a heat-conducting plate having a vapour chamber, comprising: obtaining a vapor core and a wicking layer; disposing the vapor core and the wicking layer inside a cavity defined between spaced-apart walls of a casing; injecting a working fluid inside the cavity; applying a vacuum to the cavity; and after the applying of the vacuum to the cavity, cold welding peripheries of the spaced-apart walls to one another to seal the working fluid and the vapor core and the wicking layer in the cavity.

The method as defined above and described herein may further include one or more of the following steps/features, in whole or in part, and in any combination.

In some embodiments, the applying of the vacuum to the cavity includes disposing the vapor core, the wicking layer, and the casing in a vacuum chamber and applying a vacuum to the vacuum chamber.

In some embodiments, the applying of the vacuum to the cavity includes placing the vapor core, the wicking layer, and the casing inside the vacuum chamber under vacuum prior to the injecting of the working fluid inside the cavity.

In some embodiments, the method comprises: obtaining a second wicking layer; and enclosing the vapor core between the wicking layer and the second wicking layer.

In some embodiments, the disposing of the vapor core and the wicking layer inside the cavity includes disposing the vapor core and the wicking layer inside the cavity defined by the spaced-apart walls being claddings of two different materials.

In some embodiments, the disposing of the vapor core and the wicking layer inside the cavity defined by the spaced-apart walls includes disposing the vapor core and the wicking layer inside the cavity defined by the spaced-apart walls being aluminum-copper cladding casings or stainless-steel-copper cladding casings.

In some embodiments, the injecting of the working fluid includes injecting water over a recessed portion defined by a first casing portion of the casing.

In some embodiments, the method includes disposing the vapor core and the wicking layer over the first casing portion and wherein the injecting of the working fluid includes injecting the working fluid in the wicking layer.

In some embodiments, the obtaining of the vapor core and the wicking layer includes obtaining the wicking layer being a metal foam, sintered metal powder, and/or one or more layer of metal mesh.

In some embodiments, the method comprises bonding the wicking layer to one of the spaced-apart walls.

In some embodiments, the method comprises: securing the wicking layer to one of the spaced-apart walls to obtain a first sub-assembly; securing the second wicking layer to the other of the spaced-apart walls to obtain a second sub-assembly; and enclosing the vapor core between the first sub-assembly and the second sub-assembly.

In some embodiments, the method comprises bending the vapor core, the wicking layer, and the casing in a shape defining an elbow before the cold welding.

In some embodiments, the method comprises bending the vapor core, the wicking layer, and the casing in a shape defining an elbow after the cold welding.

In some embodiments, the obtaining of the vapor core includes obtaining the vapor core being a hydrophobic porous layer, a nylon mesh, a polymer mesh, and/or pillars.

In some embodiments, the vapor core includes a plurality of vapor core strips and wherein the wicking layer includes a plurality of wicking layer strips, the method comprising disposing the vapor core strips and the wicking layer strips interspaced between one another inside the cavity.

In another aspect, there is provided a heat-conducting plate having a vapor chamber, comprising: a first casing and a second casing defining a cavity therebetween; a core assembly having a wicking layer adjacent an inner side of the first casing, and a vapor core, the wicking layer and the vapor core received within the cavity; and a working fluid within the cavity, wherein a first peripheral flange of the first casing is sealingly bonded to a second peripheral flange of the second casing along a full uninterrupted perimeter of the first and second casings, the first casing joined to the second casing via the first and second peripheral flanges.

The heat-conducting plate as defined above and described herein may further include one or more of the following features, in whole or in part, and in any combination.

In some embodiments, the first casing and the second casing include a cladding of two different materials.

In some embodiments, the two different materials include aluminum and copper, the inner side of the first casing and the inner side of the second casing defined by the copper.

In some embodiments, a melting point of one of the two different materials is below a hot welding temperature of the other of the two different materials.

In some embodiments, the wicking layer includes a metal foam, sintered metal powder, and/or one or more layer of metal mesh.

In some embodiments, the vapor core includes a hydrophobic porous layer, a nylon mesh, a polymer mesh, and/or pillars.

In some embodiments, a melting point of the vapor core is below a hot welding temperature of the first casing.

In some embodiments, the wicking layer is bonded to the first casing, a second wicking layer being bonded to the second casing, the vapor core disposed between the wicking layer and the second wicking layer.

In some embodiments, the wicking layer includes a plurality of wicking layer strips and wherein the vapor core includes a plurality of vapor core strips, the wicking layer strips and the vapor core strips interspaced between one another within the cavity.

In yet another aspect, there is provided an electric power module for powering electric equipment, comprising: an enclosure having an inner volume; a battery located within the inner volume of the enclosure; a heat sink; and a heat conducting plate, the battery in heat exchange relationship with the heat sink via the heat conducting plate, the heat-conducting plate having: a first casing and a second casing defining a cavity therebetween; a core assembly having a wicking layer adjacent an inner side of the first casing, and a vapor core, the wicking layer and the vapor core received within the cavity; and a working fluid within the cavity, wherein a first peripheral flange of the first casing is sealingly bonded to a second peripheral flange of the second casing along a full uninterrupted perimeter of the first and second casings, the first casing joined to the second casing via the first and second peripheral flanges.

The electric power module as defined above and described herein may further include one or more of the following features, in whole or in part, and in any combination.

In some embodiments, the wicking layer is bonded to the first casing, a second wicking layer being bonded to the second casing, the vapor core disposed between the wicking layer and the second wicking layer.

In some embodiments, the wicking layer includes a plurality of wicking layer strips and wherein the vapor core includes a plurality of vapor core strips, the wicking layer strips and the vapor core strips interspaced between one another within the cavity.

Many further features and combinations thereof concerning the present improvements will appear to those skilled in the art following a reading of the instant disclosure.

### BRIEF DESCRIPTION OF THE DRAWINGS

FIG. 1 is a schematic representation of a battery cooling system of a vehicle;

FIG. 2 is a three dimensional partially cut-away view of a heat-conducting plate in accordance with one embodiment to be used with the battery cooling system of FIG. 1;

FIG. 3 is an enlarged view of a portion of FIG. 2;

FIG. 4 is a schematic cross-sectional view illustrating a layered structure of the heat-conducting plate of FIG. 2; and

FIG. 5 is a schematic cross-sectional view of the heat-conducting plate of FIG. 2 illustrating a process of heat exchange;

FIGS. 6A to 6C are schematic side views illustrating steps of manufacturing the heat-conducting plate of FIG. 2;

FIG. 7 is a schematic cross-sectional view illustrating a layered structure in accordance with another embodiment;

FIG. 8 is a top view of a heat-conducting plate in accordance with another embodiment;

FIG. 9 is a cross-sectional view of the heat-conducting plate of FIG. 8 taken along line A-A on FIG. 8;

FIG. 10 is a flow chart illustrating a method of manufacturing the heat-conducting plate; and

FIGS. 11A to 11C are side views of heat-conducting plates in accordance with alternate embodiments.

### DETAILED DESCRIPTION

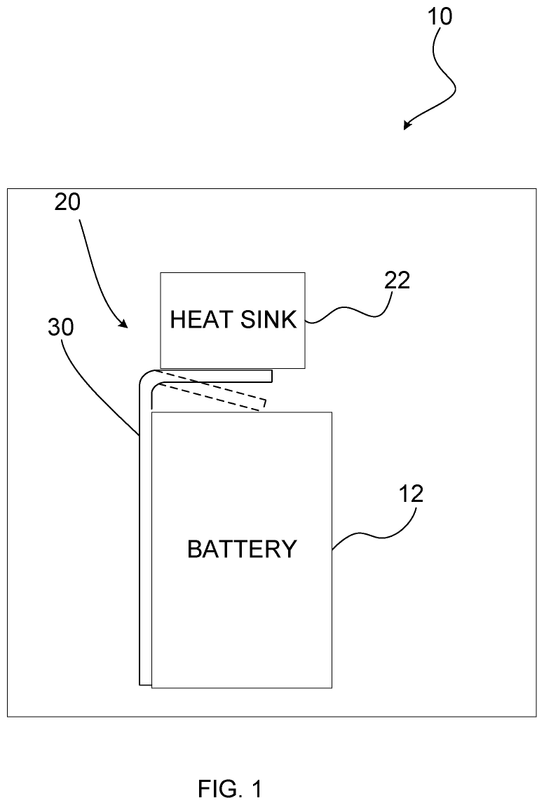

Referring now to FIG. 1, an electric power module, which may be used inside a vehicle 10 is shown and includes a cooling system 20 for cooling one or more electric batteries 12 (only one being shown in FIG. 1) of the vehicle 10. The cooling system 20 includes a heat-conducting plate 30 that is in heat exchange relationship with the battery 12 for absorbing heat from the battery or for transmitting heat to the battery 12. In the present embodiment, the heat-conducting plate 30 thermally contacts the battery 12 so that heat may be transferred between the battery 12 and the heat-conducting plate 30 by conduction.

In one particular embodiment, the heat-conducting plate 30 may be selectively moved between heat-transfer and heat-isolation positions as depicted with solid and dashed lines, respectively, in FIG. 1. Although not shown, an actuator may be located between the heat-conducting plate 30 and the battery 12 to impart movement of the heat-conducting plate 30 between the heat-transfer and heat-isolation positions. However, it is to be understood that the cooling system 20 and the heat-conducting plate 30 as described herein may be used in other applications, including for the thermal management of any types of electrical batteries and/or battery packs. They may for example not include any switchable or moveable portion of the heat-conducting plate 30.

A heat sink 22 of the cooling system 20 may be used to draw heat from the battery 12 via the heat-conducting plate 30. The heat sink 22 may be any suitable device operable for heat exchange. The heat sink 22 may include, for instance, fins, a conduit flowing a coolant, and so on. The heat sink 22 may be a heat source in an alternate configuration to provide heat to the battery 12 via the heat-conducting plate 30.

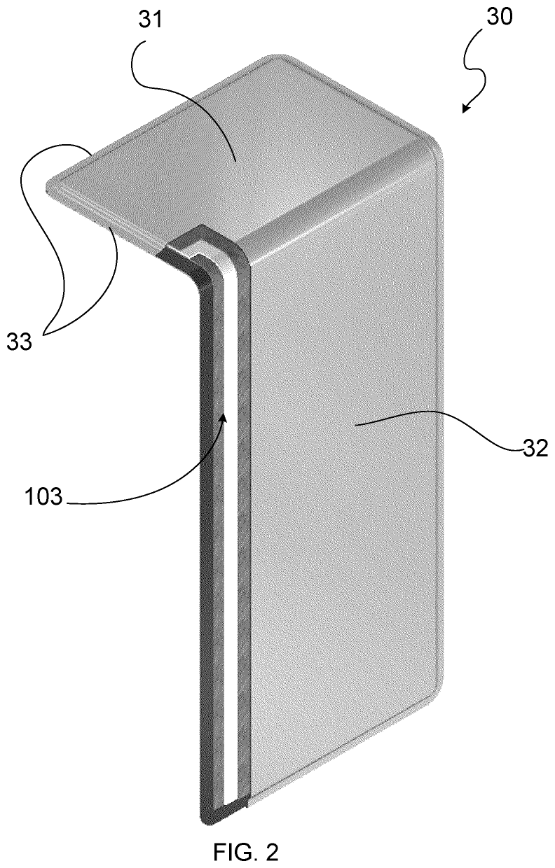

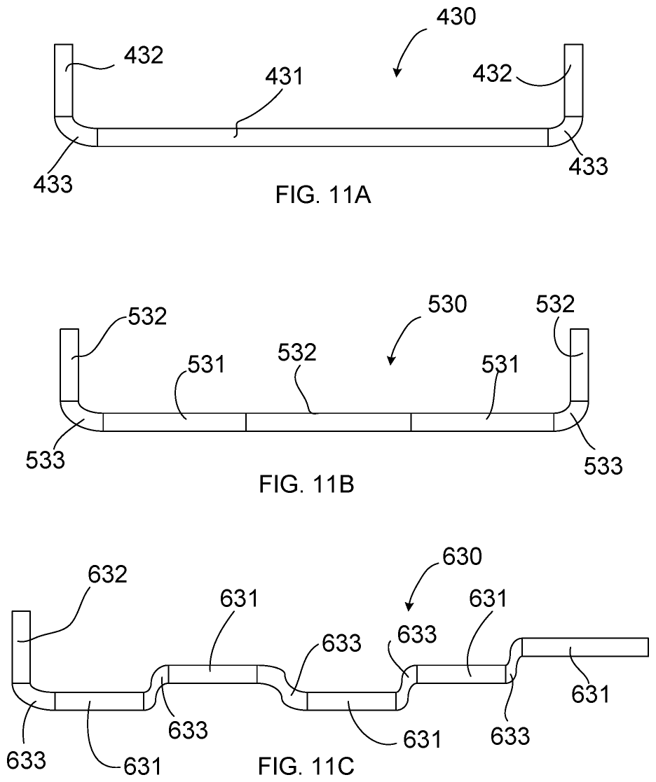

Referring now to FIGS. 2-4, the heat-conducting plate 30 is described in greater detail. In the depicted embodiment, the heat-conducting plate 30 includes a first section 31, which may be referred to as the condenser section, and a second section 32, which may be referred to as the evaporator section, generally transverse to the first section 31 such that the heat-conducting plate 30 in the depicted embodiment has a L-shape. It will be appreciated that other suitable shapes may be alternately used, as will be described below with reference to FIGS. 11A to 11C. A shape in which the first section 31 and the second section 32 are joined via an elbow is contemplated. In certain embodiments, this elbow may define an internal angle of approximately 90 degrees (e.g. 90 degrees±10%) between the first and second sections of the heat-conducting plate, however, this angle may be different (e.g., greater or less) than 90 degrees±10%. The first section 31 may be pivotable relative to the second section 32 about an axis defined by an intersection between the first section 31 and the second section 32. The first section 31 may be moved between the heat-transfer position and the heat-isolation position shown in FIG. 1. The second section 32 may be in contact with the battery 12, when installed in abutting relationship with the battery as shown in FIG. 1. Although the heat-conducting plate 30 depicted in FIG. 2 has a bend therein to form its L-shape, it is to be understood that the heat-conducting plate 30 as described herein may also be a flat (i.e. non-bent) plate.

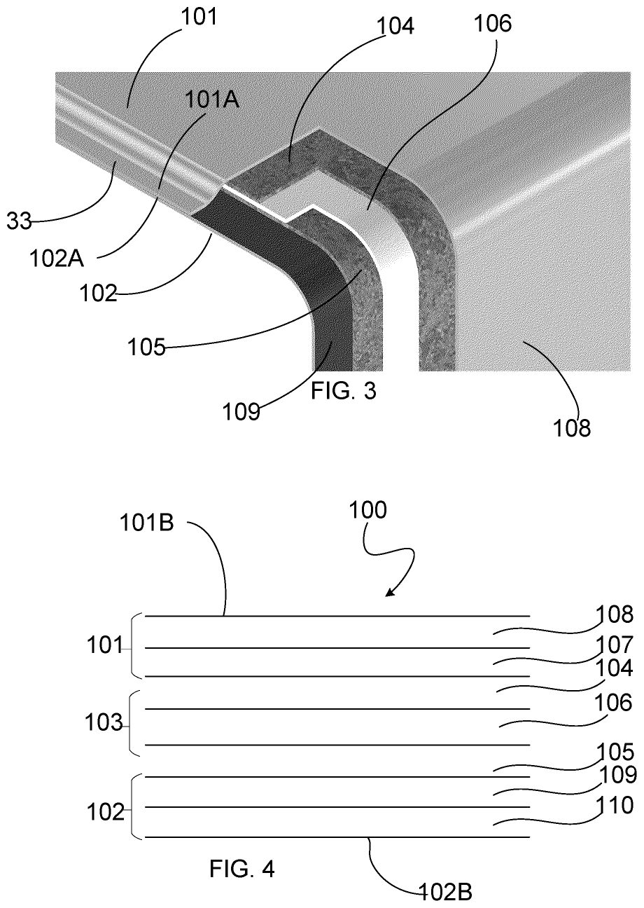

Referring more particularly to FIGS. 3-4, the heat-conducting plate 30 has a layered structure 100. The layered structure 100 includes an outer envelope or casing that is composed of a first casing portion 101 and a second casing portion 102 (hereinafter simply referred to as first casing 101 and second casing 102). A cavity 103 is defined between the first casing 101 and the second casing 102. The cavity 103 may be referred to alternatively as a vapor chamber, or vapor core. The first casing 101 is joined to the second casing 102 along a periphery 33 of the heat-conducting plate 30, as will be described in further detail below. More specifically, a first peripheral flange 101A of the first casing 101 abuts and is sealingly fixed to a second peripheral flange 102A of the second casing 102 along a full uninterrupted perimeter of the first and second casings 101, 102. The first casing 101 is joined to the second casing 102 via the first and second peripheral flanges 101A, 102A. Further details about the manner in which the first casing 101 and the second casing 102 are joined in this manner are provided below.

In the context of the present disclosure, the expression “sealingly fixed” implies that the first and second peripheral flanges 101A, 102A are secured to one another in a permanent matter. In other words, the bonding between the first and second peripheral flanges 101A, 102A is permanent and forms a hermetic seal such that a pressure inside the cavity 103 remains constant regardless of pressure variations of an environment outside the cavity 103. This permanent bonding, as will be discussed below, may be created by rendering the first and second peripheral flanges 101A, 102A different parts of a monolithic body.

Still referring to FIGS. 3-4, in the embodiment shown, the cavity 103 is defined by the first casing 101 having a first wall 101B being offset from the first peripheral flange 101A to define a recessed portion. The second casing 102 has a second wall 102B (FIG. 4) that may be offset from the second peripheral flange 102A. When the first casing 101 is secured to the second casing 102 via their respective first and second peripheral flanges 101A, 102A, the first and second walls 101B, 102B (see FIG. 4, for example) are spaced apart from one another. The cavity 103 is thereby defined between the first and second walls 101B, 102B. It will be appreciated that only one of the first and second walls 101B, 102B may be offset from its corresponding first and second peripheral flanges 101A, 102A to create the space between the first and second walls 101B, 102B. In some cases, both of the first and second walls 101B, 102B are offset from the first and second peripheral flanges 101A, 102A.

In an alternate embodiment, a spacer may be sandwiched between the first and second walls 101B, 102B, such as to create the space therebetween that forms the cavity 103. One or more spacers may however only be needed where the plate is at its fullest thickness, above the porous layers 105 and 104. At the peripheral flange, the two casing portions 101 and 102 remain in direct contact for cold welding. In some cases, the spacer may correspond to an increased thickness of the first and/or second casing 101, 102 at the first and/or second peripheral flanges 101A, 102A.

The heat-conducting plate 30 also includes, within the cavity 103 defined within the outer casing formed by the first and second casings 101, 102, a core assembly including a first wicking layer 104 and a second wicking layer 105. The first wicking layer 104 is disposed adjacent the first casing 101. The second wicking layer 105 is disposed adjacent the second casing 102. The core assembly further includes a vapor core 106 disposed between the first wicking layer 104 and the second wicking layer 105. Accordingly, a sandwiched core sub-assembly fills the cavity 103 defined between the inner surfaces of the walls of the first and second casings 102, the sandwiched core sub-assembly being composed of the first wicking layer 104, the vapor core 106, and the second wicking layer 105.

As it will be understood, the first wicking layer 104 and the second wicking layer 105 could be of any shape and or dimension, and may be, for example, channel-shaped and micrometric (with a dimension below about 1 mm). The first and second wicking layers 104, 105 may each have a thickness of from 0.3 mm to 2 mm, more particularly a thickness of from 0.5 mm to 1.5 mm, and more preferably about 1 mm (±10%). They may be formed of continuous ridges or discontinuous fins. The space between fins forms a two-dimensional array of interconnected micro-channels. The wicking structures may include copper screen mesh, sintered powder, metal foam and/or metal fiber. The wicking structures may be bonded to the casings. The first wicking layer 104 and the second wicking layer 105 may be metal weaving net, porous metal sintered powder, or fiber bundles. The size of the pores defined by the first and second wicking layers 104, 105 may be smaller than the thickness and may range from 30 microns to 500 microns. They may include sintered metal powder, screen, and grooved wicks. The first wicking layer 104 and the second wicking layer 105 may be hydrophilic, either by being made of a hydrophilic material or by being treated to become hydrophilic. Any suitable process to render the wicking layers hydrophilic, such as oxygen plasma, hydrogen reduction, and thermal oxidation, chemical oxidation are contemplated. The wicking layers may be sintered on the casings. The wicking layers may include multiple layers of metal mesh. The wicking layer can be formed of an array of pillars or microchannels, where the space between them acts to wick the liquid. When a liquid is present in the wicking layers 104, 105, a meniscus may be formed, which creates a capillary pressure due to surface tension of the liquid. For a hydrophilic wicking layer, the liquid may be drawn into the wicking layer and towards zones where the liquid is evaporating. A small pore size increases the capillary pressure which may enhance the transport of the liquid. Permeability of the wicking layer may also be affected by the pore size, as well as the tortuosity of the flow paths along the pores or microchannels. The wicking layer may have a high ratio of permeability to pore size. High hydrophilicity (low contact angle of the fluid) may also be desired

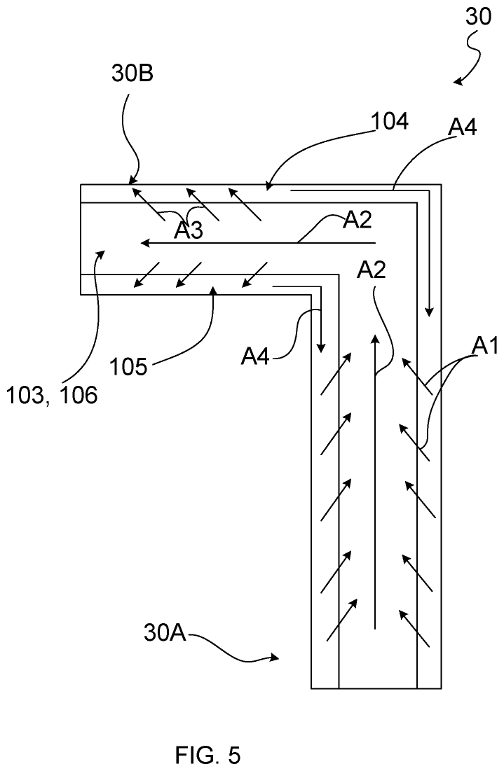

The vapor core 106 may be made of any suitable material having porosities. The vapor core 106 may include a polymeric material, such as nylon (e.g., nylon mesh). The vapor core 106 may be used as a spacer inside the cavity 103 to maintain a distance between the first wicking layer 104 and the second wicking layer 105 when the heat-conducting plate 30 is bent as shown in FIG. 1. The vapor core 106 may be made of metal, such as stainless steel. It may be made of copper. The vapor core 106 may define pores that are bigger than pores defined by the first and second wicking layers 104, 105 to ensure that the working fluid (e.g., water) gets pulled into the first and second wicking layers 104, 105 and frees the vapor core 106 to allow a continuous flow of the vapor. In some embodiments, the working fluid may be alcohol, acetone, or methanol. Any suitable combinations of fluids may be used as the working fluid. This process is described in further detail below with reference to FIG. 5. The vapor core 106 may be hydrophobic, either by being made of a hydrophobic material or by being treated to become hydrophobic. For instance, the vapor core 106 may be coated with a hydrophobic coating. Any suitable process to render the vapor core 106 hydrophobic is contemplated. The vapor core 106 may include a plurality of posts or pillars distributed along the cavity 103 to maintain the distance between the two wicking layers. The vapor core 106 may be bonded to the wicking layers 104, 105. When it is bonded, it may prevent the casings 101, 102, from deforming outward if the pressure within the vapor chamber exceeds the surrounding pressure. This may occur when the sealed plate is heated above the saturation temperature that corresponds to the surrounding pressure, such as 100 degrees Celsius at atmospheric pressure.

The first and second casings 101, 102 may be made of copper. However, copper is a very expensive and dense material and efforts are made to try to limit its usage for these reasons. In an alternate embodiment, the first casing 101 may be made of copper clad (e.g., copper with aluminum or stainless steel) while the second casing 102 is a thin copper sheet. The thicker copper clad may provide stiffness to the heat-conducting plate 30. In some embodiments, one of the first and second casings 101, 102 may be part of the battery pack, such as one wall of a casing of the battery pack.

Referring to FIG. 4, the first casing portion 101 and the second casing 102 each include two layers, namely, the first casing portion 101 includes a first inner layer 107 facing the cavity 103 and a first outer layer 108 facing an environment outside the cavity 103. Similarly, the second casing 102 includes a second inner layer 109 facing the cavity 103 and a second outer layer 110 facing the environment. In the present embodiment, the first and second inner layers 107, 109 are made of copper and the first and second outer layers 108, 110 are made of aluminum. It will be appreciated that the first and second inner layers 107, 109 may be made of any material having high thermal conductivity and being suitably resistant to corrosion because it is exposed to a working fluid flowing in the cavity 103. For instance, nickel may be used for the inner layers 107, 109. As will be understood below, the material selected to define the inner side of the first and second casings 101, 102 should be suitable for cold welding. The first and second outer layers 108, 110 may be made of any material having a high thermal conductivity. In some embodiments, the thermal conductivity may be less if a thickness of the first and second outer layers 108, 110 is sufficiently small to offer a small resistance to heat transfer. The first casing 101 and the second casing 102 may therefore be made of a clad material, such as an aluminum-copper clad. In the embodiment shown, a thickness of the first casing 101 and of the second casing 102 is composed at about 95% of the first and second outer layers 108, 110 (e.g., aluminum) and composed at about 5% of the first and second inner layers 107, 109 (e.g., copper). For instance, if a thickness of the first casing portion 101 is of 1 cm, a thickness of the first outer layer 108 may be of 9.5 mm and a thickness of the first inner layer 107 may be of 0.5 mm. In certain embodiments, the thickness of the first and second inner layer 107, 109 may be from 50 to 100 microns. Herein, the expression “about” implies variations of plus or minus 10% such that “about 10” includes a range of from 9 to 11. In the present embodiment, a thickness of each of the first and second inner layers 107, 109 is about from 50 to 100 microns. Having the first and second casing portions 101, 102 including a thin layer of copper with a thicker layer of aluminum may provide costs benefits for the manufacturing of the heat-conducting plate 30 without impairing thermal performance of the heat-conducting plate 30.

In the embodiment shown, the first and second inner layers 107, 109 extend all the way to the periphery 33 of the heat-conducting plate 30 such that the first and second inner layers 107, 109 may be in contact against one another after a joining process of the first casing 101 to the second casing 102 via their respective peripheral flanges 101A, 102A as will be described below. However, in some other embodiments, the first and second inner layers 107, 109 may overlap solely the cavity 103 and the periphery 33 of the heat-conducting plate 30 may be free of the first and second inner layers 107, 109. In such a case, the first and second outer layers 108, 110 may be contacting one another after the joining of the first and second casing portions 101, 102.

Referring now to FIG. 5, the different components of the heat-conducting plate 30 having been described above, the operation of the heat-conducting plate 30 is now described.

The heat-conducting plate 30 has a first end 30A, also referred to as an evaporator section, which may be in contact with a hot component (e.g., a battery) from which heat is to be removed. A second end 30B, also referred to as a condenser section, may be in contact with a heat sink to extract the heat. The heat-conducting plate 30 is operable to move the heat from the first end 30A to the second end 30B. To this end, the working fluid is present in liquid form in the first and second wicking layers 104, 105. It will be understood that the heat-conducting plate may also move heat from the second end 30B towards the first end 30A. In such a case, the second end 30B acts as the evaporator section and the first end 30A as the condenser section. When exposed to the heat, the working fluid evaporates in a gaseous phase and migrates, along arrows A1, towards the cavity 103, which contains the vapor core 106. The working fluid in gaseous phase then migrates along arrows A2 along the vapor core 106 towards the second end 30B of the heat-conducting plate 30. Since the second end 30B is colder than the first end 30A, the working fluid condensates back into a liquid phase and gets absorbed by the first and second wicking layers 104, 105 along arrows A3. Then, the working fluid moves, by capillary action, along the first and second wicking layers 104, 105 and migrates along arrows A4 back towards the first end 30A and the process starts over again. The heat-conducting plate 30 therefore removes heat from the first end 30A by evaporating the working fluid and transfers heat to the second end 30B by condensing the working fluid. These phase changes result in heat being moved from the first end 30A to the second end 30B. In an application where the component (i.e. battery) must be heated instead of cooled, then the inverse behavior and direction of the liquid and vapor flows are inverted, without any change to the plate structure.

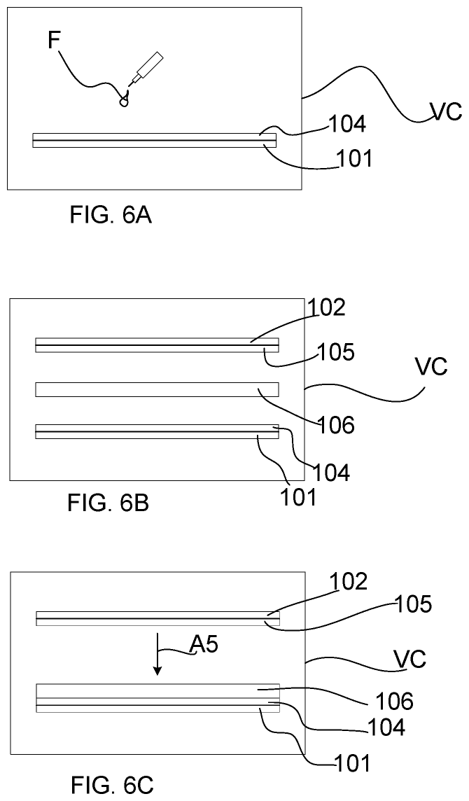

Referring now to FIGS. 6A to 6C, steps of manufacturing the heat-conducting plate 30 is shown. In the embodiment shown in FIG. 6A, the first wicking layer 104 is bonded to an inner side of the first casing 101 to obtain a first sub-assembly. At which point, the working fluid F may be injected inside the first wicking layer 104. As shown in FIG. 6B, the second wicking layer 105 may be bonded to an inner side of the second casing 102 to obtain a second sub-assembly. It will be appreciated that the working fluid F may be injected into one or both of the first and second wicking layers 104, 105. The vapor core 106 is then inserted between the two sub-assemblies. As shown in FIG. 6C, a vacuum may be created to remove air from the cavity defined between the first and second casing portions 101, 102 and the two sub-assemblies may be bonded together via the peripheries of the first and second casing portions 101, 102. As shown in FIG. 6A, the injecting of the working fluid may be done by injecting the working fluid over the first wicking layer 104. In some cases, the working fluid may be injected over the whole core assembly including the first wicking layer 104, the second wicking layer 105, and the vapor core 106. As shown in FIG. 6B, the disposing of the core assembly inside the cavity 103 may include disposing the core assembly between the two casing portions 101, 102. This may be done after or before the injecting of the working fluid. As shown in FIG. 6C, the cold welding process may include moving the second casing 102 along arrows A5 towards the first casing portion 101 until the peripheral flanges 101A, 102A of the first and second casing portions 101, 102 are in contact with one another. The cold welding process may include any suitable cold welding process.

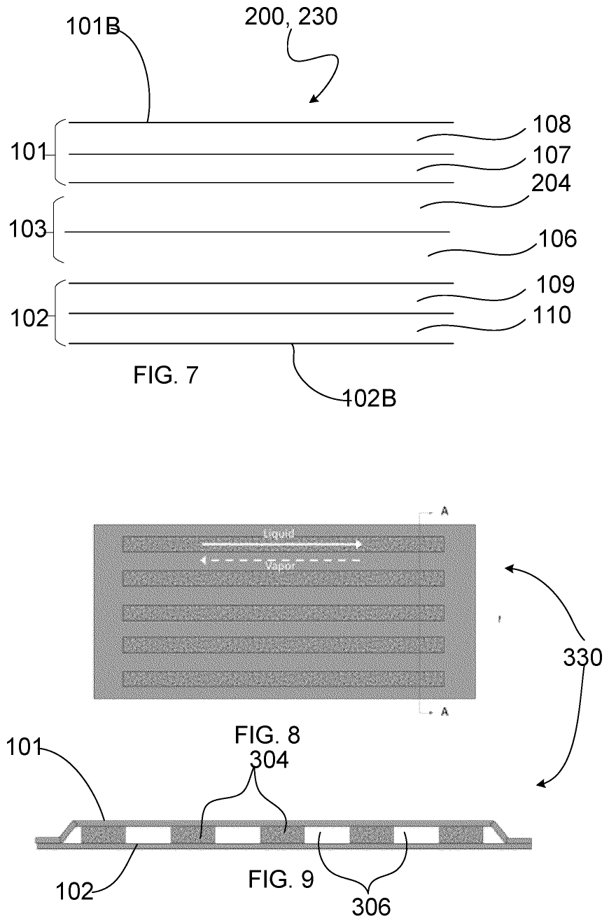

Referring to FIG. 7, another embodiment of a layered structure 200 for a heat conducting plate 230 is shown. For the sake of conciseness, only elements differing from the layered structure 100 described above are described herein below.

The layered structure 200 includes a wicking layer 204 located adjacent to an inner side of the first casing 101. The wicking layer 204 may be bonded to the inner side of the first casing 101 (or second casing 102). The layered structure 200 includes the vapor core 106 sandwiched between the wicking layer 204 and the second casing 102. Hence, in the embodiment shown, only one layer of wicking material is used.

Referring now to FIGS. 8-9, another embodiment of a heat conducting plate is shown at 330. The heat-conducting plate 330 includes the first and second casings 101, 102 described herein above. In the present embodiment, the vapor core includes a plurality of vapor core strips 306 and the wicking layer includes a plurality of wicking layer strips 304. The vapor core strips 306 and the wicking layer strips 304 are interspaced between on another as shown in FIG. 9. Each of the wicking layer strips 304 is disposed adjacent a respective one of the vapor core strips 306. Hence, the staggering of the wicking layer and vapor core is achieved within a plane parallel to the first and second casing portions 101, 102 instead of along a direction normal to the first and second casing portions 101, 102. The wicking layer strips 304 and the vapor core strips 306 extend in a direction having a component parallel to a direction of heat transfer.

In the embodiment shown, the heat-conducting plate has a single layer that is non-uniform and that encompasses both of the wicking material and the vapor core material. In the embodiment shown, the strips 304, 306 extend in a direction of heat transport, that is, between the evaporator end and the condenser end of the heat-conducting plate.

In some embodiments, a material may not be necessary in the vapor core strips 306 since the strips 304 of wicking material may be in contact with the two walls, thereby supporting external forces and maintaining the height of the vapor core. In other words, the vapor core strips 306 may be free of a material. Liquid and vapor may therefore circulate in the same plane as opposed to in planes on top of each other. This may reduce the thickness. It may be interesting for batteries since the heat flux may not be high but thickness and cost are important.

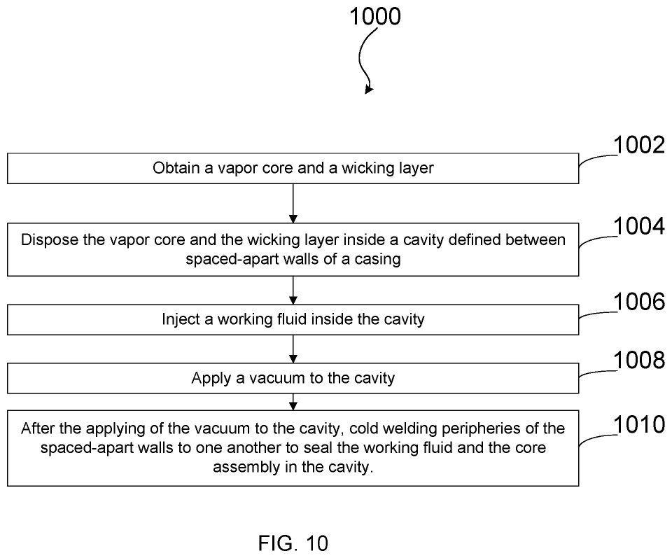

Referring now to FIG. 10, a method of manufacturing the heat-conducting plate 30, 230, 330 is shown at 1000. The method 1000 includes obtaining the vapor core 106, 306 and the wicking layer 104, 204, 304 at 1002; disposing the vapor core 106, 306 and the wicking layer 104, 204, 304 inside the cavity between the two casing portions 101, 102 at 1004; injecting the working fluid F inside the cavity at 1006; applying a vacuum to the cavity at 1008; and after the applying of the vacuum to the cavity, cold welding peripheries of the first and second casing portions 101, 102 to one another to seal the working fluid inside the cavity at 1010. The step of applying the vacuum to the cavity at 1008 may include, for example, placing the vapor core, the wicking layer, and the casing inside the vacuum chamber, applying a vacuum within the vacuum chamber, and then injecting of the working fluid F inside the cavity at 1006. It is to be understood however that in an alternate embodiment, the vacuum within the cavity may be alternately applied, including for example without placing the entirety of the casing within a vacuum chamber.

In the embodiment depicted in FIG. 3, the method 1000 includes obtaining the second wicking layer 105; and enclosing the vapor core 106 between the first wicking layer 104 and the second wicking layer 105. This may include securing (e.g., bonding) the first wicking layer 104 to the first casing portion 101 to create a first sub-assembly; securing the second wicking layer 105 to the second casing portion 102 to obtain a second sub-assembly; and enclosing the vapor core 106 between the first sub-assembly and the second sub-assembly.

Alternatively, and as shown in FIG. 7, only a single wicking layer 204 is used and bonded to the first casing portion 101 whereas the vapor core 106 is disposed adjacent the second casing portion 102. The working fluid F may injected into the single wicking layer 204 and/or the vapor core 106. The vapor core 106 may be bonded to the second casing portion 102. The first and second casing portions 101, 102 may be interchangeable. If the heat flux (heating and cooling) are both on the same side, the wicking layer 204 may only be required on that side. This configuration may reduce the cost and make the heat-conducting plate thinner.

“Cold welding” as used herein in understood to mean a contact welding or contact bonding process, wherein little to no heat is used to fuse or otherwise join the two metals—in this case the peripheral flanges 101A, 102A of the walls of the casing. Unlike a hot welding (i.e. fusion welding, such as arc welding, laser welding, brazing, soldering etc.) process, the metals being joined by cold welding do not become molten from heat. Instead, the energy used for reacting the cold weld comes in the form of pressure, rather than heat. Accordingly, the cold welding process as used herein can be performed at low temperatures, which may include room temperature for example. The process used to cold weld the peripheral flanges 101A, 102A of the walls 101B, 102B of the casing is consequently performed at a temperature that is much less than 100 degrees Celsius, such as to avoid the working fluid (which may be water) within the present heat-conducting plate from boiling and rapidly evaporating. The inserted amount of working liquid is the sum of the evaporated amount plus the desired final amount required for proper operation of the device. Sealing the device using cold welding may therefore enable the device to be filled with the working fluid before the sealing process, unlike typical vapor chambers that require sealing in two steps since the first sealing step is done at high temperature.

In the embodiment shown, applying a vacuum to the cavity 103 at 1008 includes disposing the vapor core, the wicking layer(s) and the casing in a vacuum chamber VC and applying a vacuum to the vacuum chamber VC. The cold welding of the peripheries, i.e. the peripheral flanges 101A, 102A, of the spaced-apart walls 101B, 102B at 1010 may include cold welding the peripheries using any suitable cold welding process. The disposing of the vapor core and the wicking layer(s) inside the cavity 103 at 1004 may include disposing the vapor core and the wicking layer(s) inside the cavity 103 defined by the spaced-apart walls being claddings of two different materials, which may be aluminum-copper or stainless-steel-copper claddings. The injecting of the working fluid at 1006 may include injecting water over a recessed portion defined by the first casing portion 101. The working fluid may be injected in the first and/or wicking layers 104, 105 once fixed to their respective casing portions 101, 102. Even if its upside-down, the working fluid may remain in the wicking layers because of the surface tension. In some embodiments, the working fluid is injected in both of the first and second wicking layers 104, 105. The vapor core and the wicking layer(s) may be disposed over the first casing portion 101 and the injecting of the working fluid at 1006 may include injecting the working fluid in the vapor core and the wicking layer(s). The obtaining of the vapor core and the wicking layer(s) at 1002 may includes obtaining the first wicking layer 104 and the second wicking layer 105 being a metal foam, sintered metal powder, and/or one or more layer of metal mesh. The first wicking layer 104 may be bonded one of the spaced-apart walls 101B, 102B and the second wicking layer 105 may be bonded to the other of the spaced-apart walls 101B, 102B. The obtaining of the vapor core 106 at 1002 may include obtaining the vapor core 106 being a hydrophobic porous layer, a nylon mesh, a polymer mesh, and/or pillars.

The method 1000 may include bending the vapor core and the wicking layer(s) and the casing in a L-shape before the cold welding. It may include bending the vapor core and the wicking layer(s) and the casing in a L-shape after the cold welding. If the bending is carried after the cold welding at 1010, one of the two casing portions 101, 102 may be provided with pleats at the intersection with the first and second sections 31, 32 (FIG. 2) of the heat-conducting plate 30 such that the bending does not stretch the one of the two casing portions 101, 102. These pleats may act as an accordion.

The application of a vacuum at 1008 may be done to remove all of the air inside the vacuum chamber VC. This may further have the effect of lowering a pressure inside the cavity 103, which consequently lowers an evaporation temperature of the working fluid F (e.g., water). At which point, a periphery of the first casing portion 101 may be cold welded to a periphery of the second casing 102 to seal the cavity 103 defined between the first casing portion 101 and the second casing 102 thereby enclosing the working fluid F in the cavity 103.

In the present embodiment, the two peripheral flanges 101A, 102A are contacting one another along a full uninterrupted perimeter of the heat-conducting plate 30. Consequently, there is no need of a filling tube, which would create a local spacing between the flanges 101A, 102A. The joining of the two peripheral flanges 101A, 102A by cold welding under vacuum conditions may allow to avoid using the filling tube, which would be required after a traditional hot welding process. The avoidance of the filling tube may provide the heat-conducting plate 30 free of any sharp edge or protuberance along its circumference. The heat-conducting plate 30 may therefore be more suitable for use in environment where the heat-conducting plate 30 is located within a pouch cell where the presence of a sharp edge may damage the pouch. Similarly, by being free of any sharp edge, damage to surrounding wires may be limited. The absence of the filling tube may increase an effective area of contact between the heat-conducting plate 30 and the battery 12 and heat sink 22. The removal of the tube may reduce manufacturing costs of the heat-conducting plate 30.

brazed. The cold welding may allow to minimize the presence of oxides at the interface between the two casings, provide clean surfaces, and may allow the application of high pressure along the entire perimeter of the seal between the two casings.

In the present case, a melting point of one of the two different materials of the cladding material is below a welding temperature of the other of the two different materials. Consequently, hot or traditional welding of the copper may not work, and is thus undesirable, because it might melt the aluminum and/or cause the working fluid enclosed within the casing to evaporate. Accordingly, a melting point of the vapor core 106 is below a welding temperature of the first casing 101. Consequently, hot welding the first casing 101 to the second casing 102 may be detrimental to the vapor core 106 since the latter might melt and/or cause the fluid therein to evaporate. Cold welding is used in the present embodiment because it may limit evaporation of the working fluid.

Referring now to FIGS. 11A to 11C, alternate embodiments of heat-conducting plates are shown at 430, 530, 630, respectively. For the sake of conciseness, only features differing from the other heat-conducting plates described above are described below. The heat-conducting plates 430, 530, 630 may include any of the layering structure of the heat-conducting plate 30 as described above with reference to FIGS. 4, 7, and 8.

Referring to FIG. 11A, the heat-conducing plate 430 has a U-shape and includes an evaporator section 431 and two condenser sections 432 which are laterally spaced apart from each other on either side of the evaporator section 431. Each of the two condenser sections 432 extend transversally (and in this case, upward) from a respective edge of the evaporator section 431. The evaporator section 431 is connected to the condenser sections 432 via adiabatic sections 433, which form elbows. These adiabatic sections 433 may be thermally insulated such that heat is neither expelled from nor absorbed by the heat-conducting plate 430 at the adiabatic sections 433. In the embodiment shown, the elbows defined by the adiabatic sections 433 define an angle between the evaporator section 431 and the condenser sections 432 is approximately 90 degrees (e.g. 90 degrees±10%), but other suitable angles may also be used.

Referring to FIG. 11B, the heat-conducing plate 530 has a U-shape and includes two evaporator sections 531 and three condenser sections 532. One of the condenser sections 532 is disposed between the two evaporator sections 531 and is co-planar with the two evaporator sections 531. The other two condenser sections 532 each extend transversally from a respective one of the two evaporator sections 531. Adiabatic sections 533 are used to connect two of the condenser sections 532 to the evaporator sections 531, and form elbows such that the condenser sections 532 are disposed at an angle relative to the adjacent evaporator sections 431.

Referring now to FIG. 11C, the heat-conducting plate 630 has an exemplary shape that may be tailored to fit in any suitable space. In the present case, the heat-conducting plate 630 includes five evaporator sections 631 and one condenser section 632 interconnected to one another via adiabatic sections 633, defining an elbow between at least one condenser section 632 and at least one evaporator section 631. More condenser sections may also be provided, and fewer or more evaporator sections may also be used. Herein, each of the five evaporator sections 631 are parallel to one another, but at a different height (i.e., they are non-coplanar), and the condenser section 632 extends generally transversally (and in this case upward) to the evaporator sections 631 at one lateral edge of the heat-conducting plate 630.

The embodiments described in this document provide non-limiting examples of possible implementations of the present technology. Upon review of the present disclosure, a person of ordinary skill in the art will recognize that changes may be made to the embodiments described herein without departing from the scope of the present technology. Yet further modification could be implemented by a person of ordinary skill in the art in view of the present disclosure, which modifications would be within the scope of the present technology.

1. A method of manufacturing a heat-conducting plate having a vapour chamber, comprising:
obtaining a vapor core and a wicking layer;
disposing the vapor core and the wicking layer inside a cavity defined between spaced-apart walls of a casing;
injecting a working fluid inside the cavity;
applying a vacuum to the cavity; and
after the applying of the vacuum to the cavity, cold welding peripheries of the spaced-apart walls to one another to seal the working fluid and the vapor core and the wicking layer in the cavity.

2. The method of claim 1, wherein the applying of the vacuum to the cavity includes disposing the vapor core, the wicking layer and the casing in a vacuum chamber and applying a vacuum to the vacuum chamber.

3. The method of claim 2, wherein the applying of the vacuum to the cavity includes placing the vapor core, the wicking layer, and the casing inside the vacuum chamber under vacuum prior to the injecting of the working fluid inside the cavity.

4. The method of claim 1, comprising:
obtaining a second wicking layer; and
enclosing the vapor core between the wicking layer and the second wicking layer.

5. The method of claim 1, wherein the disposing of the vapor core and the wicking layer inside the cavity includes disposing the vapor core and the wicking layer inside the cavity defined by the spaced-apart walls being claddings of two different materials.

6. The method of claim 5, wherein the disposing of the vapor core and the wicking layer inside the cavity defined by the spaced-apart walls includes disposing the vapor core and the wicking layer inside the cavity defined by the spaced-apart walls being aluminum-copper cladding casings or stainless-steel-copper cladding casings.

7. The method of claim 1, wherein the injecting of the working fluid includes injecting water over a recessed portion defined by a first casing portion of the casing.

8. The method of claim 7, including disposing the vapor core and the wicking layer over the first casing portion and wherein the injecting of the working fluid includes injecting the working fluid in the wicking layer.

9. The method of claim 1, wherein the obtaining of the vapor core and the wicking layer includes obtaining the wicking layer being a metal foam, sintered metal powder, and/or one or more layer of metal mesh.

10. The method of claim 1, comprising bonding the wicking layer to one of the spaced-apart walls.

11. The method of claim 4, comprising:
securing the wicking layer to one of the spaced-apart walls to obtain a first sub-assembly;
securing the second wicking layer to the other of the spaced-apart walls to obtain a second sub-assembly; and
enclosing the vapor core between the first sub-assembly and the second sub-assembly.

12. The method of claim 1, comprising bending the vapor core, the wicking layer, and the casing in a shape defining an elbow before the cold welding.

13. The method of claim 1, comprising bending the vapor core, the wicking layer, and the casing in a shape defining an elbow after the cold welding.

14. The method of claim 1, wherein the obtaining of the vapor core includes obtaining the vapor core being a hydrophobic porous layer, a nylon mesh, a polymer mesh, and/or pillars.

15. The method of claim 1, wherein the vapor core includes a plurality of vapor core strips and wherein the wicking layer includes a wicking layer strips, further comprising disposing the vapor core strips and the wicking layer strips interspaced between one another inside the cavity.

16. A heat-conducting plate having a vapor chamber, comprising:
a first casing and a second casing defining a cavity therebetween;
a core assembly having
a wicking layer adjacent an inner side of the first casing, and
a vapor core, the wicking layer and the vapor core received within the cavity; and
a working fluid within the cavity,
wherein a first peripheral flange of the first casing is sealingly bonded to a second peripheral flange of the second casing along a full uninterrupted perimeter of the first and second casings, the first casing joined to the second casing via the first and second peripheral flanges.

17. The heat-conducting plate of claim 16, wherein the first casing and the second casing include a cladding of two different materials.

18. (canceled)

19. The heat-conducting plate of claim 17, wherein a melting point of one of the two different materials is below a hot welding temperature of the other of the two different materials.

20. (canceled)

21. (canceled)

22. The heat-conducting plate of claim 16, wherein a melting point of the vapor core is below a hot welding temperature of the first casing.

23. The heat-conducting plate of claim 16, wherein the wicking layer is bonded to the first casing, a second wicking layer being bonded to the second casing, the vapor core disposed between the wicking layer and the second wicking layer.

24. (canceled)

25. An electric power module for powering electric equipment, comprising:
an enclosure having an inner volume;
a battery located within the inner volume of the enclosure;
a heat sink; and
a heat conducting plate, the battery in heat exchange relationship with the heat sink via the heat conducting plate, the heat conducting plate having:
a first casing and a second casing defining a cavity therebetween;
a core assembly having
a wicking layer adjacent an inner side of the first casing, and
a vapor core, the wicking layer and the vapor core received within the cavity; and
a working fluid within the cavity,
wherein a first peripheral flange of the first casing is sealingly bonded to a second peripheral flange of the second casing along a full uninterrupted perimeter of the first and second casings, the first casing joined to the second casing via the first and second peripheral flanges.

26. (canceled)

27. (canceled)

28. A method of manufacturing a heat-conducting plate having a vapour chamber, comprising:
obtaining a vapor core and a wicking layer;
disposing the vapor core and the wicking layer inside a cavity defined between spaced-apart walls of a casing;
injecting a working fluid inside the cavity;
applying a vacuum to the cavity; and
after the applying of the vacuum to the cavity, sealingly bonding peripheries of the spaced-apart walls to one another about a full uninterrupted perimeter of the casing to seal the working fluid and the vapor core and the wicking layer in the cavity.

29. The method of claim 28, wherein the sealingly bonding of the peripheries of the spaced-apart walls of the casing is performed while maintaining a temperature of the working fluid inside the cavity below a boiling point of the working fluid.

30. The method of claim 29, wherein the sealingly bonding of the peripheries of the spaced-apart walls of the casing includes cold-welding.
